(19) United States
(12) Patent Application Publication
(10) Pub. No.: US 2016/0344398 A1
(43) Pub. Date: Nov. 24, 2016

(54) METHODS AND SYSTEMS FOR CASCADED PHASE-LOCKED LOOPS (PLLS)

(71) Applicant: MaxLinear, Inc., Carlsbad, CA (US)

(72) Inventors: Prasun Kali Bhattacharyya, Bangalore (IN); Prasenjit Bhowmik, Bangalore (IN); Vamsi Paidi, Irvine, CA (US)

(21) Appl. No.: 15/160,496

(22) Filed: May 20, 2016

Related U.S. Application Data
(60) Provisional application No. 62/194,561, filed on Jul. 20, 2015.

(30) Foreign Application Priority Data
May 22, 2015 (IN) 1453/DEL/2015

(51) Int. Cl. H03L 7/23; H03L 7/089

(52) U.S. Cl. CPC H03L 7/235; H03L 7/0891

(57) ABSTRACT

Systems and methods are provided for cascaded phase-locked loops (PLLs). A plurality of phase-locked loops (PLLs) arranged in a cascaded manner may be used in providing enhanced signal generation. Each PLL generates an output based on a corresponding input and a feedback signal. The input to a first one of plurality of cascaded phase-locked loops (PLLs) comprises an input reference signal; the input to each remaining one of the plurality of the cascaded phase-locked loops (PLLs) corresponds to an output of a preceding one of the plurality of the cascaded phase-locked loops (PLLs); and the output of a last one of the plurality of cascaded phase-locked loops (PLLs) corresponds to an overall output signal of the plurality of cascaded phase-locked loops (PLLs). The frequency of the overall output signal is set based on the one or more adjustments applied in each one of the plurality of cascaded phase-locked loops (PLLs).

### CLAIM OF PRIORITY

This patent application makes reference to, claims priority to and claims benefit from each of Indian Provisional Patent Application Serial No. 1453/DEL/2015, filed May 22, 2015, and U.S. Provisional Patent Application Ser. No. 62/194,561, filed Jul. 20, 2015. Each of the above identified applications is hereby incorporated herein by reference in its entirety.

### TECHNICAL FIELD

Aspects of the present disclosure relate to signal processing. More specifically, various implementations of the present disclosure relate to cascaded phase-locked loops (PLLs).

### BACKGROUND

Conventional approaches for implementing and using phase-locked loops (PLLs), such as voltage-controlled-oscillator (VCO) based PLLs, may be costly, cumbersome, or inefficient—e.g., they may have limited frequency ranges. Further limitations and disadvantages of conventional and traditional approaches will become apparent to one of skill in the art, through comparison of such systems with some aspects of the present disclosure as set forth in the remainder of the present application with reference to the drawings.

### BRIEF SUMMARY

System and methods are provided for cascaded phase-locked loops (PLLs), substantially as shown in and/or described in connection with at least one of the figures, as set forth more completely in the claims.

These and other advantages, aspects and novel features of the present disclosure, as well as details of an illustrated embodiment thereof, will be more fully understood from the following description and drawings.

### BRIEF DESCRIPTION OF SEVERAL VIEWS OF THE DRAWINGS

FIG. 1 illustrates an example electronic system that may utilize phase-locked loops (PLLs).

FIG. 2 illustrates an example non-cascaded phase-locked loop (PLL).

FIG. 3 illustrates an example implementation of cascaded phase-locked loops (PLLs), in accordance with the present disclosure.

FIG. 4 illustrates a flowchart of an example process for configuring and operating a cascaded phase-locked loops (PLLs) arrangement.

### DETAILED DESCRIPTION OF THE INVENTION

As utilized herein the terms “circuits” and “circuitry” refer to physical electronic components (e.g., hardware) and any software and/or firmware (“code”) which may configure the hardware, be executed by the hardware, and or otherwise be associated with the hardware. As used herein, for example, a particular processor and memory may comprise a first “circuit” when executing a first one or more lines of code and may comprise a second “circuit” when executing a second one or more lines of code. As utilized herein, “and/or” means any one or more of the items in the list joined by “and/or”. As an example, “x and/or y” means any element of the three-element set {(x), (y), (x, y)}. In other words, “x and/or y” means “one or both of x and y.” As another example, “x, y, and/or z” means any element of the seven-element set {(x), (y), (z), (x, y), (x, z), (y, z), (x, y, z)}. In other words, “x, y and/or z” means “one or more of x, y, and z.” As utilized herein, the term “exemplary” means serving as a non-limiting example, instance, or illustration. As utilized herein, the terms “for example” and “e.g.” set off lists of one or more non-limiting examples, instances, or illustrations. As utilized herein, circuitry is “operable” to perform a function whenever the circuitry comprises the necessary hardware and code (if any is necessary) to perform the function, regardless of whether performance of the function is disabled or not enabled (e.g., by a user-configurable setting, factory trim, etc.).

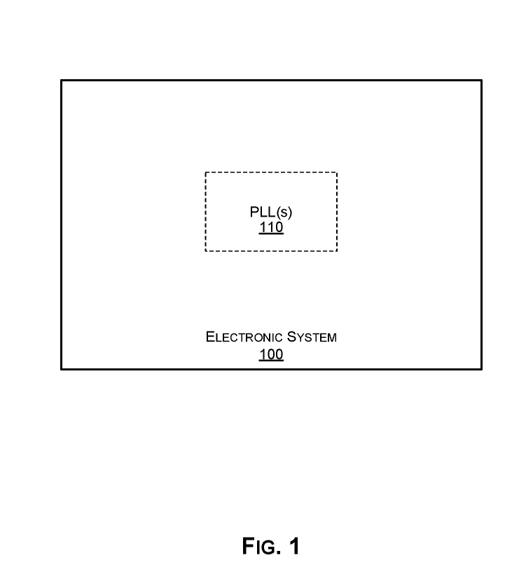

FIG. 1 illustrates an example electronic system that may utilize phase-locked loops (PLLs). Shown in FIG. 1 is an electronic system 100.

The electronic system 100 may comprise suitable circuitry for implementing various aspects of the present disclosure. The electronic system 100 may be configured to support performing, executing or running various operations, functions, applications and/or services. The electronic system 100 may be used, for example, in executing computer programs, playing video and/or audio content, gaming, performing communication applications or services (e.g., Internet access and/or browsing, email, text messaging, chatting and/or voice calling services), providing networking services (e.g., WiFi hotspot, Bluetooth piconet, Ethernet networking, cable or satellite systems, and/or active 4G/3G/femtocell data channels), or the like.

In some instances, the electronic system 100 may enable and/or support communication of data. In this regard, the electronic system 100 may need to communicate with other systems (local or remote), such as during executing, running, and/or performing of operations, functions, applications and/or services supported by the electronic system 100. For example, the electronic system 100 may be configured to support (e.g., using suitable dedicated communication components or subsystems) use of wired and/or wireless connections/interfaces, which may be configured in accordance with one or more supported wireless and/or wired protocols or standards, to facilitate transmission and/or reception of signals (carrying data) to and/or from the electronic system 100. In this regard, the electronic system 100 may be operable to process transmitted and/or received signals in accordance with applicable wired or wireless protocols.

Examples of wireless standards, protocols, and/or interfaces that may be supported and/or used by the electronic system 100 may comprise wireless personal area network (WPAN) protocols, such as Bluetooth (IEEE 802.15); near field communication (NFC) standards; wireless local area network (WLAN) protocols, such as WiFi (IEEE 802.11); cellular standards, such as 2G/2G+(e.g., GSM/GPRS/EDGE, and IS-95 or cdmaOne) and/or 2G/2G+(e.g., CDMA2000, UMTS, and HSPA); 4G standards, such as WiMAX (IEEE 802.16) and LTE; Ultra-Wideband (UWB), and/or the like.

Examples of wired standards, protocols, and/or interfaces that may be supported and/or used by the electronic system 100 may comprise Ethernet (IEEE 802.3), Fiber Distributed Data Interface (FDDI), Integrated Services Digital Network (ISDN), cable television and/or internet access standards (e.g., ATSC, DVB-C, DOCSIS, etc.), in-home distribution standards such as Multimedia over Coax Alliance (MoCA), and Universal Serial Bus (USB) based interfaces.

Examples of signal processing operations that may be performed by the electronic system 100 may comprise, for example, filtering, amplification, analog-to-digital conversion and/or digital-to-analog conversion, up-conversion/down-conversion of baseband signals, encoding/decoding, encryption/decryption, and/or modulation/demodulation.

In some instances, the electronic system 100 may be configured to support input/output (I/O) operations, to enable receiving input from and/or providing output to users. Accordingly, the electronic system 100 may comprise components or subsystems for obtaining user input and/or providing output to the user. For example, the electronic system 100 may support input/output (I/O) operations for allowing user interactions which may be needed for controlling the electronic system 100 or operations thereof—e.g., allowing users to provide input or commands, for controlling certain functions or components of the electronic system 100, and/or to output or provide feedback pertaining to functions or components. The electronic system 100 may also support input/output (I/O) operations in conjunction with use of data (e.g., multimedia content). For example, the electronic system 100 may support generating, processing, and/or outputting of video and/or acoustic signals, such as via suitable output devices or components (e.g., displays, loudspeakers, etc.). In this regard, the output signals may be generated based on content, which may be in digital form (e.g., digitally formatted music or the like). Similarly, the electronic system 100 may support capturing and processing of video and/or acoustic signals, such as via suitable input devices or components (e.g., cameras, microphones, etc.), to generate (e.g., to store or communicate) corresponding data. The corresponding data may be in digital form (e.g., digitally formatted music, video, or the like).

The electronic system 100 may be a stationary system (e.g., being installed at, and/or configured for use only in particular location). In other instances, however, the electronic system 100 may be a mobile device—i.e. intended for use on the move and/or at different locations. In this regard, the electronic system 100 may be designed and/or configured (e.g., as handheld device) to allow for ease of movement, such as to allow it to be readily moved while being held by the user as the user moves, and the electronic system 100 may be configured to perform at least some of the operations, functions, applications and/or services supported on the move.

Examples of electronic systems may comprise handheld electronic devices (e.g., cellular phones, smartphones, or tablets), computers (e.g., laptops, desktops, or servers), dedicated media devices (e.g., televisions, game consoles, or portable media players, etc.), set-top boxes (STBs) or other similar receiver systems, and the like. The disclosure, however, is not limited to any particular type of electronic system.

In operation, the electronic system 100 may be operable to perform various operations, functions, applications and/or services. For example, in some instances, electronic system 100 may be operable to communicate (send and/or receive) data, and to process the communicated data. In this regard, communication of data, whether over wired or wireless interfaces, may typically comprise transmitting and/or receiving signals that are communicated over wireless and/or wired connections. For example, analog radio frequency (RF) signals may be used to carry data (e.g., content), with the data being embedded into the analog signals in accordance with particular analog or digital modulation schemes. For analog communications, data is transferred using continuously varying analog signals, and for digital communications, the analog signals are used to transfer discrete messages in accordance with a particular digitalization scheme.

Accordingly, handling of the various operations, functions, applications and/or services supported or performed in the electronic system 100 may require performing various signal processing operations—e.g., to facilitate processing of data, reception and processing signals, generation and transmission of signals, extracting of data from or embedding into signals, and the like. Such signal processing may require use of various circuits that may perform and/or support various functions or operations.

For example the electronic system 100 may comprise one or more phase lock loops (PLLs). Each PLL 100 may comprise suitable circuitry for generating an output signal whose phase may be related to the phase of an input signal. In this regard, PLLs may be used to generate outputs (signals) that may be kept locked, in phase, to the PLLs' inputs (e.g., signals). In other words, PLLs may be configured such that their output signal(s) and the input signal(s) remain locked to one another—e.g., in phase. Keeping the input and output phase in lock may also allow keeping the input and output frequencies the same. Consequently, in addition to synchronizing signals, a phase locked loop may be used to track an input frequency, or it can generate a frequency that is a multiple of the input frequency.

Therefore, PLLs may be utilized as control systems or components, providing signals for use in such operation as clock synchronization, demodulation, frequency synthesis, and the like. For example, PLLs may be utilized in radio, television, communications, computers and other electronic applications. In this regard, PLLs may be utilized in these systems to demodulate signals, recover signals (e.g., from noisy communication channels), generate a stable frequency at multiples of an input frequency (e.g., for frequency synthesis), and/or distribute precisely timed clock pulses (e.g., in digital circuits such as microprocessors).

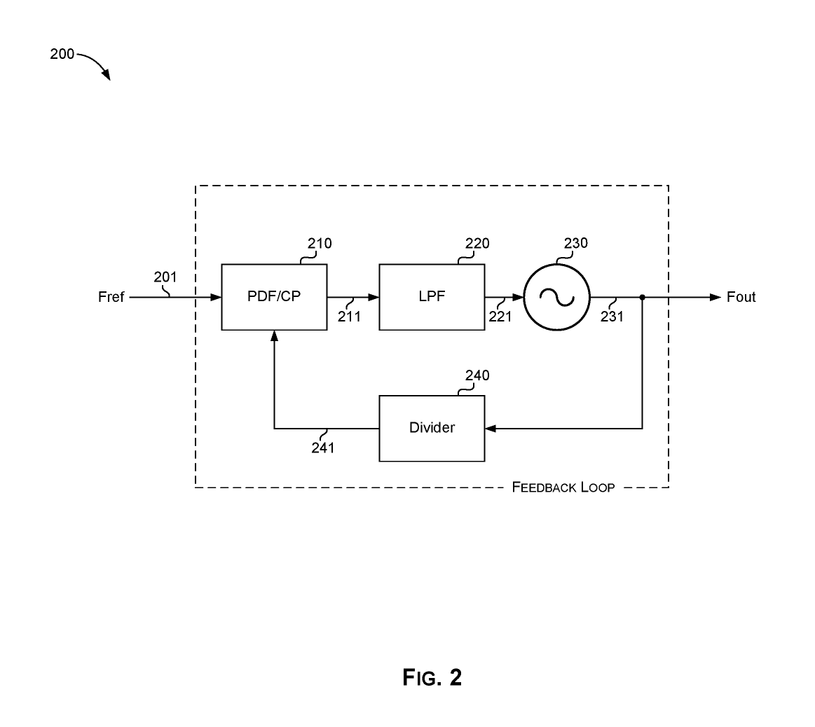

Various architectures and/or designs may be used in implementing phase lock loops (PLLs). In its most basic implementation, a conventional phase locked loop may comprise, for example, a variable frequency oscillator component and a phase detector, with the frequency oscillator component generating a periodic signal and the phase detector comparing the phase of that generated signal with the phase of an input signal of the phase detector—e.g., to adjust the oscillator component generating, based on the comparison, to keep the phases matched. PLLs may function based on feeding back. In this regard, the output signal of the PLL may be “fed back” toward the input signal of the PLL—that is the output signal is brought back toward the input signal for comparison, thus forming a loop. An example implementation is shown in FIG. 2.

FIG. 2 illustrates an example non-cascaded phase-locked loop (PLL). Shown in FIG. 2 is a phase locked loop (PLL) 200.

The PLL 200 may be similar to the PLL 100 of FIG. 1, for example. In this regard, the PLL 200 may comprise suitable circuitry for generating an output signal whose phase may be related to (e.g., locked to) phase of an input signal. In the example implementation shown in FIG. 1, the PLL 200 may comprise a phase frequency detector/charge pump (PFD/CHP) block 210, a loop filter (LPF) 220, a voltage controlled oscillator (VCO) 230, and a divider 240. The PLL 200 may receive an input (reference) signal F_{ref} 201 and generate a corresponding output signal Fₒᵤₜ 231. The input (reference) signal F_{ref} 201 may be, for example, a periodic crystal clock signal, generated by a crystal (not shown).

The PFD/CHP block 210 may comprise suitable circuitry for detection of phase and/or frequency difference, and for applying adjustments (e.g., to a block input), such as based on detected differences and/or other inputs. In particular, with respect to the phase and/or frequency detection, the PFD/CHP block 210 may be operable to detect the difference in phase and/or frequency between the input signal 115 (a reference signal) and feedback signal 241 (outputted by the divider 240), and generate a corresponding error information (e.g., signal) based on (e.g., proportional to) the phase differences. The error information (signal) may be used in adjusting the frequency at which the VCO 230 is operating (e.g., adjust the VCO 230 to operate at a higher or lower frequency). The PFD/CHP block 210 may be operable to output charge (or current) adjustment based on the error information (signal), such as using charge pumping. For example, via the output 211, the PFD/CHP block 210 may be operable to drive current into LPF 220 to ‘up’ (increase) the frequency, or draw current from the LPF 220 to ‘down’ (lower) the frequency.

The LPF 220 may comprise suitable circuitry for applying the changes to the VCO 230, such as by converting the charge (current) adjustments 211 applied by the PFD/CHP block 210 into a control voltage 221 that is used to bias the VCO 230. The LPF 220 may be, for example, a low-pass filter.

The VCO 230 may comprise suitable circuitry that may be operable to function as an electronic oscillator whose oscillation frequency is controlled by a voltage input (e.g., the control voltage 221). The VCO 230 may generate an output 231 representing the output of the PLL 200. In addition to the actual intended uses (for the PLL 200), the output 231 of VCO 230 may be looped back, for use in controlling phase (and frequency) of signals of the PLL 200. In this regard, the divider 240 may be inserted in the feedback loop to produce a frequency synthesizer, so as to allow the VCO 230 frequency above the frequency of the reference signal F_{ref} 201.

In accordance with the present disclosure, performance of conventional PLLs may be enhanced, in an optimized manner. For example, in various example implementations of the present disclosure, modified architectures may be used to enable use of PLLs with a large programmable frequency range while using an input reference frequency of relaxed phase-noise. Such architectures may be used, for example, to provide a low phase-noise clock synthesizer with large programmable frequency range. In a conventional PLL (e.g., PLL 200), the loop-bandwidth may be limited (e.g., to 1/10th of frequency of the input (reference) signal) for stability. Further, beyond the unity-gain bandwidth (UGB) of the PLL-loop, PLL phase-noise is typically limited by VCO phase-noise. To generate a low phase-noise clock with large programmable frequency-range, a low phase-noise VCO with large tuning-range may be required. Low phase-noise VCOs may be invariably designed with high-Q inductor/capacitor (LC) tanks; but low phase-noise LC-based VCOs typically may have small tuning-range.

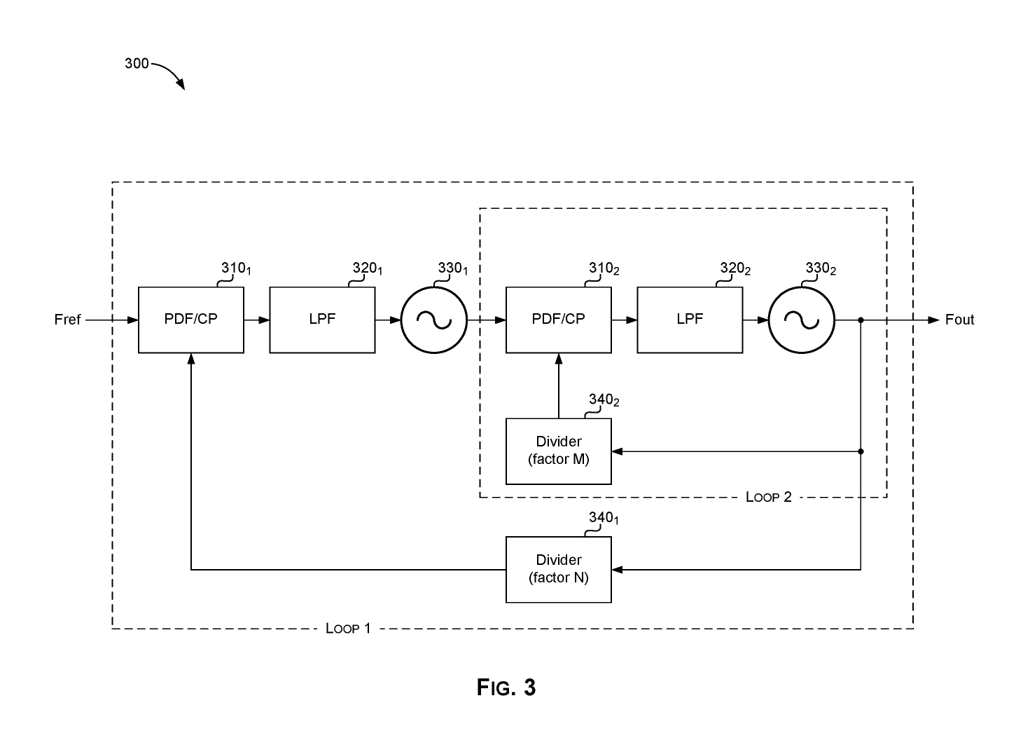

To obtain different frequencies, VCOs with different oscillation frequency may be multiplexed. Such approach may, however, increase circuit complexity, power-consumption, noise and area as multiplexing at high-frequency comes with added complexity, power consumption, its associated noise and area. Further, power-supply noise leaks into output clock through the multiplexing switches degrading its phase-noise and spurious performance. Implementations in accordance with the present disclosure may be incorporated modified and optimized architecture that may address such problems. Such architecture may comprise a low phase-noise VCO with small tuning range combined with another VCO having large tuning range whose phase-noise requirement may be relaxed. An example of such architecture is described in more detail with respect to FIG. 3.

FIG. 3 illustrates an example implementation of cascaded phase-locked loops (PLLs), in accordance with the present disclosure. Shown in FIG. 3 is a cascaded phase-locked loops (PLLs) based architecture 300.

The architecture 300 may essentially include multiple PLLs (e.g., two PLLs, as shown in the example implementation depicted in FIG. 3), or components corresponded thereto, which may be arranged such that the PLLs are effected connected in cascaded fashion, with combined feedback. As with the PLL 200 of FIG. 2, the architecture 300 may also receive an input (reference) signal F_{ref} and generate a corresponding output signal Fₒᵤₜ. For example, the architecture 300 may comprise a pair of phase frequency detector/charge pump (PFD/CHP) blocks 310₁ and 310₂, a pair of loop filters (LPFs) 320₁ and 320₂, a pair of voltage controlled oscillator (VCOs) 330₁ and 330₂, and a pair of dividers 340₁ and 340₂. In this regard, each of the PFD/CHP blocks 310₁ and 310₂, the LPFs 320₁ and 320₂, the VCOs 330₁ and 330₂, and the dividers 340₁ and 340₂ may be substantially similar to the similarly-named component (e.g., the PFD/CHP block 210, the LPF 220, the VCO 230, and the divider 240, respectively) in FIG. 2. Nonetheless, some (or all) these of components may not be identical, and may be adjusted based on the particular arrangement.

For example, each of the VCOs 330₁ and 330₂ may be configured to oscillate at particular frequency and/or may to have particular tuning range. Thus, the VCOs 330₁ and 330₂ may have different frequencies and/or different tuning ranges. Further, each of the dividers 340₁ and 340₂ may be configured to apply a particular division factor. Thus, the dividers 340₁ and 340₂ may apply different division factors (e.g., factor N for divider 340₁ for and factor M for divider 340₂, with N and M being non-zero integers). In some instances, the components may be adjusted adaptively and/or dynamically—e.g., division factors N and M may be adjusted.

As illustrated in FIG. 3, the elements of the architecture 300 may be arranged so as to create two joined PLL feedback loops (marked as “Loop_1” and “Loop_2” in FIG. 3). For example, Loop_2 may be implemented a wideband PLL-loop and Loop_1 may be implemented a narrow-band PLL-loop. In this regard, the VCO 330₁ may have small tuning range. Accordingly, the VCO 330₁ may be designed and/or implemented using a high-Q LC-tank to achieve extremely low phase-noise. It also oscillates at a frequency f₁, which may be higher than the frequency of the input (reference) signal F_{ref}. The VCO 330₂ may be a high-frequency VCO, oscillating at a frequency f₂, which may be higher than f₁. Thus, the VCO 330₂ may have large tuning range. Thus, as output of the VCO 330₁ is the input to Loop_2, unity-gain frequency of Loop_2 may be extended (e.g., up to f₁/10). The phase-noise of the VCO 330₂ may be attenuated, such as by loop-gain of Loop_2 based on the extended frequency—thus relaxing the phase-noise requirement (e.g., until reaching f₁/10).

The unity-gain frequency of Loop_1 (UGB₁) may be kept arbitrarily low to filter-out phase-noise from the input (reference) F_{ref}. Thus, phase-noise of the output Fₒᵤₜ may be determined by phase-noise of the VCO 330₁ in the frequency range [UGB₁, f₁/10]. Frequency of the output Fₒᵤₜ may be adjusted, such as by adjusting the division factor M applied in Loop_2. Further, the tuning range of the VCO 330₁ may be minimized, such as by adjusting (simultaneously) the division factor N applied in Loop_1 to a suitable value. Accordingly, overall performance of the architecture 300 may adjusted adaptively and/or dynamically, by adjusting one of more of each of the VCO frequencies (f1 and f2) and the division factors applied in the feedback loops (M and N).

Table 1, below, illustrates different combinations of values for M, N, f₁ and f₂ in particular user scenario (e.g., with input (reference) F_{ref} of 100 MHz.). As shown in the table, to vary f2, frequency of the VCO 330₂, (which corresponds to the frequency of output Fₒᵤₜ) between 20 GHz to 42 GHz, the frequency of VCO 330₁, f1, need only vary from 1.9 GHz to 2 GHz. Thus, the VCO 330₂ has a range of 20 GHz to 42 GHz, but its phase-noise can be relaxed as unity-gain frequency of Loop_2 (UGB₂) may be increased to 190 MHz while keeping the unity-gain frequency of Loop_1 (UGB₁) arbitrarily low to filter-out phase-noise of F_{ref}. Since the range of the VCO 330₁ is lower, it may achieve desired phase-noise with lower power-consumption compared to a conventional solution of multiplexed high-frequency VCOs. Further, the cascaded approach may also achieve better power-supply rejection as it avoids multiplexing switches that leak supply-noise into the output Fₒᵤₜ as may occur in conventional approaches.

TABLE 1
Example combinations of values for cascaded PLL arrangement

| F_{ref} (MHz) | f2 (GHz) | M | f1 (GHz) | N |
|---|---|---|---|---|
| 100 | 42 | 21 | 2.000000 | 420 |
| 100 | 41 | 21 | 1.952381 | 410 |
| 100 | 40 | 20 | 2.000000 | 400 |
| 100 | 39 | 20 | 1.950000 | 390 |
| 100 | 38 | 19 | 2.000000 | 380 |
| 100 | 37 | 19 | 1.947368 | 370 |
| 100 | 36 | 18 | 2.000000 | 360 |
| 100 | 35 | 18 | 1.944444 | 350 |
| 100 | 34 | 17 | 2.000000 | 340 |
| 100 | 33 | 17 | 1.941176 | 330 |
| 100 | 32 | 16 | 2.000000 | 320 |
| 100 | 31 | 16 | 1.937500 | 310 |
| 100 | 30 | 15 | 2.000000 | 300 |
| 100 | 29 | 15 | 1.933333 | 290 |
| 100 | 28 | 14 | 2.000000 | 280 |
| 100 | 27 | 14 | 1.928571 | 270 |
| 100 | 26 | 13 | 2.000000 | 260 |
| 100 | 25 | 13 | 1.923077 | 250 |
| 100 | 24 | 12 | 2.000000 | 240 |
| 100 | 23 | 12 | 1.916667 | 230 |
| 100 | 22 | 11 | 2.000000 | 220 |
| 100 | 21 | 11 | 1.909091 | 210 |
| 100 | 20 | 10 | 2.000000 | 200 |

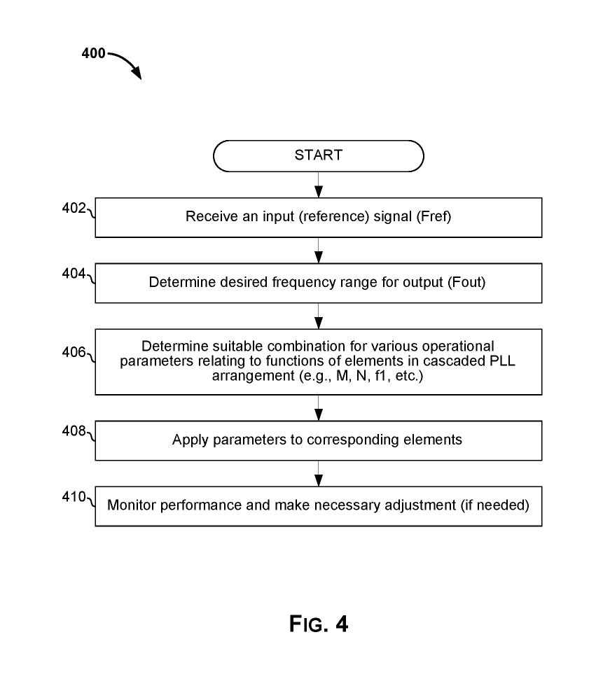

FIG. 4 illustrates a flowchart of an example process for configuring and operating a cascaded phase-locked loops (PLLs) arrangement. Shown in FIG. 4 is flow chart 400, comprising a plurality of example steps (represented as blocks 402-410), for configuring and operating a cascaded phase-locked loops (PLLs) arrangement (e.g., the arrangement of architecture 300 of FIG. 3), in accordance with the present disclosure.

In step 402, an input (reference) signal (F_{ref}) may be received.

In step 404, desired frequency range for the output (Fₒᵤₜ) may be determined.

In step 406, suitable combination(s), for achieving the desired performance, for various operational parameters relating to functions of elements in cascaded PLL arrangement (e.g., M, N, f1, etc.) may be determined.

In step 408, the parameters (as determined in the prior step) may be applied to the corresponding elements.

In step 410, performance of the arrangement may be monitored, and (if needed) necessary adjustment may be made—e.g., in a similar manner as described with respect to steps 406-408.

Other embodiments of the invention may provide a non-transitory computer readable medium and/or storage medium, and/or a non-transitory machine readable medium and/or storage medium, having stored thereon, a machine code and/or a computer program having at least one code section executable by a machine and/or a computer, thereby causing the machine and/or computer to perform the processes as described herein.

Accordingly, various embodiments in accordance with the present invention may be realized in hardware, software, or a combination of hardware and software. The present invention may be realized in a centralized fashion in at least one computing system, or in a distributed fashion where different elements are spread across several interconnected computing systems. Any kind of computing system or other apparatus adapted for carrying out the methods described herein is suited. A typical combination of hardware and software may be a general-purpose computing system with a program or other code that, when being loaded and executed, controls the computing system such that it carries out the methods described herein. Another typical implementation may comprise an application specific integrated circuit or chip.

Various embodiments in accordance with the present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A system, comprising:
a signal generator that comprises one or more circuits, wherein the signal generator is configurable to generate an output signal within a wide programmable frequency-range based on an input reference signal, the one or more circuits being operable to:
generate one or more intermediate signals based on the input reference signal and at least one feedback signal within the signal generator;
generate the output signal of the signal generator based on the one or more intermediate signals; and
set a frequency of the output signal of the signal generator based on applying one or more adjustments to the at least one feedback signal during the generation of the one or more intermediate signals.

2. The system of claim 1, wherein the one or more circuits are operable to apply to the at least one feedback signal, at least one particular adjustment associated with each of a plurality of cascading loop stages in the signal generator.

3. The system of claim 2, wherein the one or more circuits are operable to:
generate each of the one or more intermediate signals via a corresponding one of the plurality of cascading loop stages; and
generate the output signal of the signal generator via a last one of the plurality of cascading loop stages.

4. The system of claim 2, wherein the at least one particular adjustment comprises a particular division factor.

5. The system of claim 2, wherein the signal generator comprises a plurality of cascaded phase-locked loops (PLLs), each of which corresponding to one of the plurality of cascading loop stages.

6. The system of claim 1, wherein the at least one feedback signal comprises the output signal of the signal generator.

7. The system of claim 1, wherein the input reference signal has a frequency of relaxed phase-noise.

8. A method, comprising:
in a signal generator configurable to generate an output signal within a wide programmable frequency-range based on an input reference signal:
generating one or more intermediate signals based on the input reference signal and at least one feedback signal within the signal generator;
generating the output signal of the signal generator based on the one or more intermediate signals; and
set frequency of the output signal of the signal generator based on applying one or more adjustments to the at least one feedback signal during the generating of the one or more intermediate signals.

9. The method of claim 8, comprising applying to the at least one feedback signal, at least one particular adjustment associated with each of a plurality of cascading loop stages in the signal generator.

10. The method of claim 9, wherein the at least one particular adjustment comprises a particular division factor.

11. The method of claim 9, comprising:
generating each of the one or more intermediate signals via a corresponding one of the plurality of cascading loop stages; and
generating the output signal of the signal generator via a last one of the plurality of cascading loop stages.

12. The method of claim 8, wherein the at least one feedback signal comprises the output signal of the signal generator.

13. The method of claim 8, wherein the input reference signal has frequency of relaxed phase-noise.

14. A system, comprising:
a plurality of cascaded phase-locked loops (PLLs), each PLL comprises:
a voltage controlled oscillator (VCO) operable to generate an output signal of the PLL based on an input to the PLL and a feedback signal; and
an adjustment circuit operable to apply one or more adjustments to the feedback signal;
wherein:
an input to a first one of plurality of cascaded phase-locked loops (PLLs) comprises an input reference signal;
an input to each remaining one of the plurality of the cascaded phase-locked loops (PLLs) corresponds to an output of a preceding one of the plurality of the cascaded phase-locked loops (PLLs);
an output of a last one of the plurality of cascaded phase-locked loops (PLLs) corresponds to an overall output signal of the plurality of cascaded phase-locked loops (PLLs); and
a frequency of the overall output signal is based on the one or more adjustments applied in each one of the plurality of cascaded phase-locked loops (PLLs).

15. The system of claim 14, wherein the feedback signal is based on the overall output signal.

16. The system of claim 14, wherein the adjustment circuit is operable to apply a particular division factor to the feedback signal.

17. The system of claim 14, wherein each VCO of each one of the plurality of cascaded phase-locked loops (PLLs) operates at a different oscillating frequency.

18. The system of claim 14, wherein each PLL comprises one or more processing circuits for processing the input to the PLL.

19. The system of claim 14, wherein each PLL comprises a filtering circuit operable to apply filtering to the input to the PLL.

20. The system of claim 14, wherein each PLL comprises a detection and adjustment circuit operable to:
detect phase and/or frequency differences associated with the input to the PLL, and
apply to the input to the PLL one or more adjustments based on detected differences.
